(19) United States
(12) Patent Application Publication
(10) Pub. No.: US 2023/0164462 A1
(43) Pub. Date: May 25, 2023

(54) PHOTODETECTOR, SOLID-STATE IMAGE SENSOR, AND METHOD OF MANUFACTURING PHOTODETECTOR

(71) Applicant: Panasonic Intellectual Property Management Co., Ltd., Osaka (JP)

(72) Inventors: Naoki TORAZAWA, Osaka (JP); Tatsuya KABE, Osaka (JP); Yutaka HIROSE, Kyoto (JP)

(21) Appl. No.: 18/100,401

(22) Filed: Jan. 23, 2023

Related U.S. Application Data
(63) Continuation of application No. PCT/JP2021/025919, filed on Jul. 9, 2021.

(30) Foreign Application Priority Data
Jul. 30, 2020 (JP) 2020-129154

(51) Int. Cl. H04N 25/77; H01L 27/146

(52) U.S. Cl. CPC H04N 25/77; H01L 27/14643

(57) ABSTRACT

A photodetector includes a semiconductor substrate; a photoelectric converter in the semiconductor substrate; and a condenser light-transmissive and opposed to the photoelectric converter. The condenser includes: an inorganic material layer at least partially overlapping the photoelectric converter in a plan view; and an inorganic material layer covering the inorganic material layer and having a refractive index lower than a refractive index of the inorganic material layer.

### CROSS REFERENCE TO RELATED APPLICATIONS

This is a continuation application of PCT International Application No. PCT/JP2021/025919 filed on Jul. 9, 2021, designating the United States of America, which is based on and claims priority of Japanese Patent Application No. 2020-129154 filed on Jul. 30, 2020. The entire disclosures of the above-identified applications, including the specifications, drawings and claims are incorporated herein by reference in their entirety.

### FIELD

The present disclosure relates to a photodetector, a solid-state image sensor including the photodetector, and a method of manufacturing the photodetector.

### BACKGROUND

In recent years, photon counting photodetectors utilizing avalanche photodiodes (APDs) have been developed as one type of photodetectors that detect weak light. Patent literatures (PTLs) 1 to 3 each discloses a technique related to a photodiode.

### CITATION LIST

### Patent Literature

PTL 1: Japanese Unexamined Patent Application Publication No. 2019-180048
PTL 2: Japanese Unexamined Patent Application Publication No. 2004-20957
PTL 3: Japanese Unexamined Patent Application Publication No. 2010-141358

### SUMMARY

### Technical Problem

The present disclosure provides a photodetector, for example, which can be manufactured more simply than before and exhibits a higher light collection efficiency at a photoelectric converter.

### Solution to Problem

A photodetector according to one aspect of the present disclosure includes: a semiconductor substrate; a photoelectric converter in the semiconductor substrate; and a condenser light-transmissive and opposed to the photoelectric converter. The condenser includes: a first inorganic material layer at least partially overlapping the photoelectric converter in a plan view; and a second inorganic material layer covering the first inorganic material layer and having a refractive index lower than a refractive index of the first inorganic material layer.

A solid-state image sensor according to one aspect of the present disclosure includes: a pixel array obtained by arranging photodetectors, each being the photodetector described above, in a matrix; and a readout circuit that reads a signal output from the pixel array.

A method of manufacturing a photodetector according to one aspect of the present disclosure includes: forming a photoelectric converter and a pixel separator around the photoelectric converter in a semiconductor substrate in a plan view of the semiconductor substrate; and forming a condenser opposed to the photoelectric converter and including a first inorganic material layer and a second inorganic material layer with a refractive index lower than a refractive index of the first inorganic material layer by: forming the first inorganic material layer to overlap the photoelectric converter at least partially in a plan view; and forming the second inorganic material layer to cover the first inorganic material layer.

### Advantageous Effects

The present disclosure provides a photodetector, for example, which can be manufactured more simply and exhibits a higher light collection efficiency at a photoelectric converter.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view showing a photodetector according to an embodiment.

FIG. 2 is a plan view showing a condenser according to the embodiment.

FIG. 3A is a first cross-sectional view showing a method of manufacturing the photodetector according to the embodiment.

FIG. 3B is a second cross-sectional view showing the method of manufacturing the photodetector according to the embodiment.

FIG. 3C is a third cross-sectional view showing the method of manufacturing the photodetector according to the embodiment.

FIG. 3D is a fourth cross-sectional view showing the method of manufacturing the photodetector according to the embodiment.

FIG. 4A is a graph showing a relationship between a material of an inorganic material layer included in the photodetector according to the present disclosure and the light collection efficiency.

FIG. 4B is a graph showing a relationship between a width of the inorganic material layer included in the photodetector according to the present disclosure and the light collection efficiency.

FIG. 5 is a cross-sectional view showing a photodetector according to Variation 1 of the embodiment.

FIG. 6 is a cross-sectional view showing a photodetector according to Variation 2 of the embodiment.

FIG. 7 is a cross-sectional view showing a photodetector according to Variation 3 of the embodiment.

FIG. 8 is a cross-sectional view showing a photodetector according to Variation 4 of the embodiment FIG. 9 is a plan view showing a condenser according to Variation 1.

FIG. 10 is a plan view showing a condenser according to Variation 2.

FIG. 11 is a plan view showing a condenser according to Variation 3.

FIG. 12 shows a solid-state image sensor according to an embodiment.

FIG. 13 shows a layout of a plurality of photodetectors included in the solid-state image sensor according to the embodiment.

FIG. 14 is a cross-sectional view showing an example photodetector included in the solid-state image sensor according to the embodiment.

### DESCRIPTION OF EMBODIMENT

### (Underlying Knowledge Forming Basis of the Present Disclosure)

In recent years, photon counting photodetectors have been developed which utilize APDs as photodetectors for detecting weak light. APDs are each a photodiode that multiplies a photocurrent upon application of a predetermined reverse voltage. It is an objective of a photodetector including, as a photodetector, a photodiode such as an APD to improve light collection efficiency at a photoelectric converter. At present, an on-chip lens or a gradient index lens as shown in PLTs 1 to 3 described above is suggested to improve the light collection efficiency at a photoelectric converter.

However, these lenses require advanced lithography techniques and microfabrication at a higher aspect ratio and simultaneous formation of a plurality of materials, and are thus difficult to form. Accordingly, a simple manufacturing method is necessary as a technique of improving light collection characteristics of a photodetector with pixels to be further miniaturized. There is thus a room for reviewing the technique of miniaturizing pixels and improving light collection efficiency.

Now, an embodiment of photodetectors, for example, will be described in detail with reference to the drawings. The embodiment that will be described below are general or specific examples. The numerical values, shapes, materials, constituent elements, the arrangement and connection of the constituent elements etc. shown in the embodiment below are thus mere examples, and are not intended to limit the scope of the present disclosure.

The figures are schematic representations and not necessarily drawn strictly to scale. The same reference signs represent substantially the same configurations in the drawings and redundant description will be omitted or simplified.

The drawings used for the detailed description of the following embodiment may show coordinate axes. Out of the coordinate axes, a Z-axis extends, for example, in a stacking direction and in a vertical direction. The positive side of the Z-axis may be referred to as an “upper” side, while the negative side of the Z-axis may be referred to as a “lower” side. In other words, the Z-axis is vertical to the main surface of a semiconductor substrate with a photoelectric converter (i.e., a condenser), and may also be expressed as the “stacking direction” or a “thickness” direction of the semiconductor substrate. X- and Y-axes are orthogonal to each other on a plane (e.g., horizontal plane) vertical to the Z-axis.

In the embodiment below, a “plan view” means that the photodetectors are seen along the Z-axis. In other words, in the embodiment below, the “plan view” means that the photodetector is seen along a normal of the main surface of the semiconductor substrate.

The present disclosure does not exclude a structure with conductivities inverted from those described below in the embodiment. Specifically, all the p- and n-types described below may be inverted.

### Embodiment

### [Configuration of Photodetector]

Now, a configuration of a photodetector according to an embodiment will be described in detail with reference to the drawings.

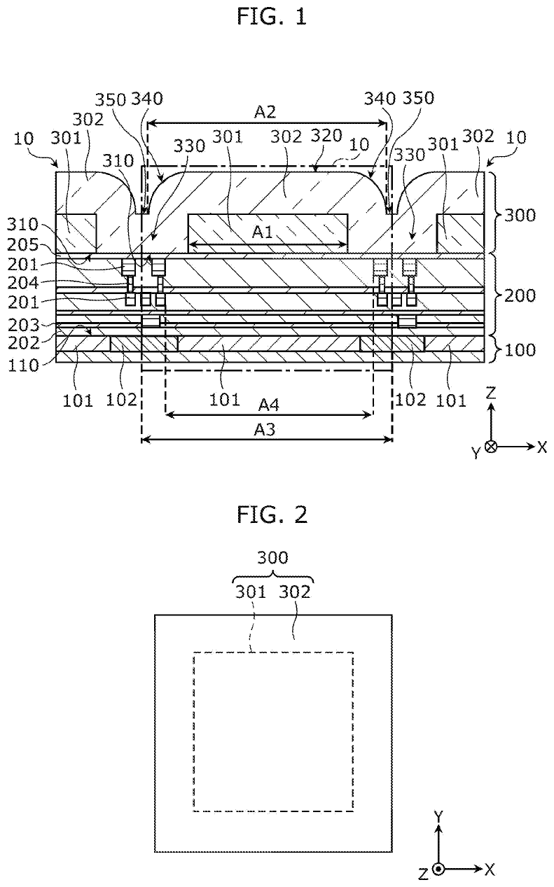

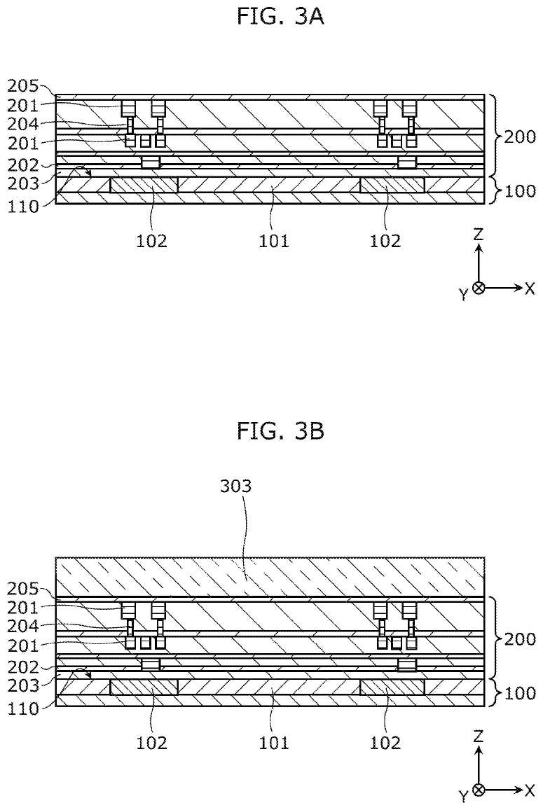

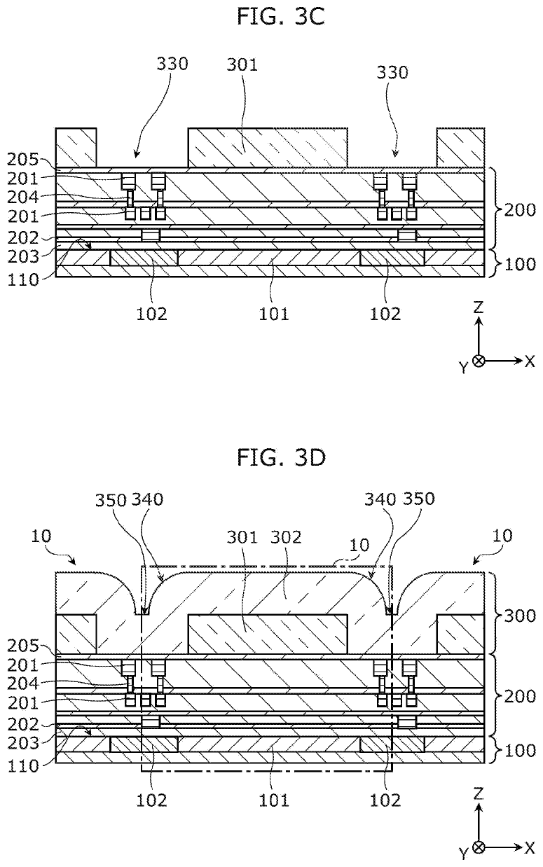

FIG. 1 is a cross-sectional view showing photodetectors 10 according to the embodiment. FIG. 1 shows parts of photodetectors 10 corresponding unit pixels in an enlarged manner. As well as FIG. 1, FIGS. 3A to 3D, 5, and 6, which will be described, show three photodetectors including those shown partially on both sides.

Photodetectors 10 photoelectrically convert incident light (also referred to as “external light”) into electricity and output the electricity. Photodetectors 10 are mainly targeted at near-infrared light. The “near-infrared light” has a wavelength within a range from 750 nm to 1400 nm, for example.

As shown in FIG. 1, photodetectors 10 include semiconductor substrate 100, multilayer 200, and condenser 300.

Semiconductor substrate 100 is made of silicon (Si), for example. Semiconductor substrate 100 may have a p- or n-type conductivity.

In the following description, the upper surface (i.e., the main surface) of semiconductor substrate 100 will also be referred to as a “light incident surface” or a “light receiving surface”.

Semiconductor substrate 100 includes photoelectric converters 101 and pixel separators 102 for separating adjacent photoelectric converters 101 into unit pixels.

Photoelectric converters 101 are located in relatively upper positions of semiconductor substrate 100 (specifically, near main surface 110 of semiconductor substrate 100) and convert incident external light into electricity, in other words, convert light into signal charges. Photoelectric converters 101 are photodiodes. The photodiodes here include avalanche photodiodes. Photoelectric converters 101 are obtained, for example, by implanting ions in the silicon substrate.

Pixel separators 102 are provided for separating pixels including photoelectric converters 101 and isolation regions (i.e., insulating regions) arranged alternately with photoelectric converters 101 in semiconductor substrate 100. Pixel separators 102 are interposed between photoelectric converters 101 included in adjacent photodetectors 10. For example, in a plan view, pixel separators 102 are located around photoelectric converters 101 in semiconductor substrate 100. Pixel separators 102 are obtained, for example, by implanting ions in the silicon substrate.

Placed on main surface 110 of semiconductor substrate 100 is multilayer 200.

Multilayer 200 is for taking out charges (i.e., signal charges) generated when photoelectric converters 101 convert the external light incident thereon into electricity. Multilayer 200 includes interconnect layers (interconnects) 201, for example. More specifically, multilayer 200 includes a plurality of interconnect layers (interconnects) 201 and a plurality of interlayer insulating films 202, a plurality of liner layers 203 including a liner layer (i.e., an uppermost liner layer) 205, and a plurality of vias 204.

Out of the plurality of liner layers 203, liner layer 205 is the uppermost liner layer. Specifically, liner layer 205 is the uppermost one of the plurality of liner layers 203 and located above one of interconnect layers 201.

Multilayer 200 has a height (i.e., a height from main surface 110 of semiconductor substrate 100 to the upper surface of multilayer 200, in other words, to lower layer 310 of condenser 300) of 1.0 μm, for example.

Formed in interconnect layers 201 are interconnects constituting circuits included in photodetectors 10, for example. Interconnect layers 201 are for transmitting the charges generated by photoelectric converters 101, for example, to readout circuit 505 which will be described later or other circuits. Interconnect layers 201 are made of copper (Cu), for example. Alternatively, interconnect layers 201 may be made of metal, such as aluminum (Al) or tungsten (W), other than copper.

In a plan view, interconnect layers 201 overlap pixel separators 102. In this embodiment, interconnect layers 201 are arranged right above pixel separators 102.

Interlayer insulating films 202 are interposed between sets of interconnect layers 201 to insulate interconnect layers 201 from each other. Interlayer insulating films 202 are silicon oxide (SiOx) or carbon-doped silicon oxide (SiOC), for example.

Liner layers 203 are interposed between a plurality of interlayer insulating films 202 or on interlayer insulating films 202 so as to stop etching at the time of manufacturing photodetectors 10 and/or reduce diffusion of metal atoms from interconnect layers 201. In this embodiment, interlayer insulating films 202 and liner layers 203 are stacked alternately. Liner layers 203 are made of silicon oxycarbide (SiCO) or silicon carbonitride (SiCN), for example.

Vias 204 are through-electrodes for electrically connecting sets of interconnect layers 201. Vias 204 are made of copper (Cu), for example. Alternatively, vias 204 may be made of metal, such as aluminum (Al) or tungsten (W), other than copper.

Located above multilayer 200 is condenser 300. In this manner, photodetectors 10 according to this embodiment include semiconductor substrate 100, multilayer 200, and condenser 300 stacked in this order. That is, photodetectors 10 are each what is called a “front side illumination (FSI)” photodetector including multilayer 200 of sets of interconnect layers 201 and interlayer insulating films 202 between the sets of interconnect layers 201, on main surface 110 of semiconductor substrate 100.

Condenser 300 is an optical member that collects external light incident from photodetectors 10 and emits the collected light toward photoelectric converters 101. Condenser 300 is light-transmissive (i.e., transmissive to light). In this embodiment, photodetectors 10 are for detecting near-infrared external light (e.g., with a wavelength within a range from about 750 nm to about 1400 nm). In this embodiment, condenser 300 is thus transmissive to (e.g., characterized to transmit 90% or more) light with a wavelength within the range from 750 nm to 1400 nm.

Condenser 300 includes inorganic material layer (or first inorganic material layer) 301 and inorganic material layer (or second inorganic material layer) 302.

Specifically, condenser 300 are opposed to photoelectric converters 101 and includes inorganic material layers 301, and inorganic material layers 302 with a refractive index lower than that of inorganic material layers 301. Inorganic material layers 301 are arranged to overlap photoelectric converters 101 at least partially in a plan view. Inorganic material layers 302 are arranged to cover inorganic material layers 301. In this embodiment, for example, inorganic material layers 301 each has an outer edge more inward than corresponding one of interconnect layers 201 that overlap pixel separators 102 in a plan view. For example, inorganic material layers 302 each includes groove 350 recessed toward semiconductor substrate 100 above corresponding one of interconnect layers 201 that overlap pixel separators 102 of semiconductor substrate 100 around photoelectric converters 101 in a plan view.

For example, in an alignment of a plurality of photodetectors 10, interconnect layers 201 are located below the gaps between adjacent inorganic material layers 301.

Liner layer (uppermost liner layer) 205 has a refractive index lower than that of inorganic material layers 301 and higher than that of inorganic material layers 302.

In this embodiment, condenser 300 is in the form of a layer (i.e., film) including inorganic material layers 301 on multilayer 200, and inorganic material layers 302 in the form of a layer to cover inorganic material layers 301.

Inorganic material layers 301 are made of a light-transmissive inorganic material. Inorganic material layers 301 are located above photoelectric converters 101. Specifically, inorganic material layers 301 overlap photoelectric converters 101 at least partially in a plan view. In this embodiment, entire inorganic material layers 301 overlap photoelectric converters 101 in a plan view. The outer edges of inorganic material layers 301 are located more inward than interconnect layers 201 not to overlap interconnect layers 201 in a plan view. The outer edge of each inorganic material layer 302 includes groove 350 above corresponding one of interconnect layers 201 in a plan view. Inorganic material layers 301 are separated from (i.e., not in contact with) adjacent inorganic material layers 301. For example, in a plan view, separation grooves 330 for separating inorganic material layers 301 from adjacent inorganic material layers 301 are formed on the outer peripheries of inorganic material layers 301 above interconnect layers 201.

Separation grooves 330 are for separating adjacent inorganic material layers 301. In this embodiment, inorganic material layers 302 fill separation grooves 330.

Inorganic material layers 302 are made of a light-transmissive inorganic material. Inorganic material layers 302 have a refractive index lower than that of inorganic material layers 301. Specifically, the inorganic material of inorganic material layers 302 has a lower refractive index than the inorganic material of inorganic material layers 301. In this embodiment, since photodetectors 10 are for detecting near-infrared external light, and inorganic material layers 302 have a lower refractive index than inorganic material layers 301 with respect to near-infrared external light.

Inorganic material layers 301 have a refractive index higher than that of inorganic material layers 302 and fall within a range from 1.6 to 2.5, for example.

Inorganic material layers 301 are films containing Si and at least any of O, N, or C, for example, or films containing Ti and O. Specifically, inorganic material layers 301 are made of silicon nitride (SiN), silicon-oxynitride (SiON), SiCN, SiCO, or titanium oxide (TiOₓ), where x is one or two.

The refractive index of inorganic material layers 302 falls within a range from 1.3 to 1.6, for example.

Inorganic material layers 302 are films containing Si and at least any of O or C, for example. Specifically, inorganic material layers 302 are made of SiOx or SiOC, for example, where x is one or two.

Inorganic material layers 302 cover inorganic material layers 301, specifically, the upper and side surfaces of inorganic material layers 301 and arranged in contact with inorganic material layers 301.

Inorganic material layers 302 are in contact with (i.e., continuous with) inorganic material layers 302 of adjacent photodetectors 10. Since there are separation grooves 330, inorganic material layers 302 have grooves 350 above separation grooves 330.

Inorganic material layers 302 of adjacent photodetectors 10 may be separated.

Condenser 300 has a height (i.e., a height from the upper surface of multilayer 200, in other words, lower layer 310 of condenser 300 to upper surface 320 of condenser 300) of 2.0 μm, for example. Inorganic material layers 301 and 302 have a height (i.e., a thickness) of 1.0 μm, for example.

Condenser 300 has widths (i.e., lengths along the X- and Y-axes) different between inorganic material layers 301 and 302.

Width A1 (e.g., the length along the X-axis shown in FIG. 1) of each inorganic material layer 301 is 4.0 μm, for example.

Width A1 of inorganic material layer 301 falls within a range from 57% to 83% of the length (i.e., distance A3) that is a width (i.e., cell size) of each photodetector 10. Specifically, in a cross-sectional view (e.g., a cross-section along the XZ-plane shown in FIG. 1) along the alignment of photoelectric converters 101 and inorganic material layers 301 (i.e., the Z-axis in this embodiment), width A1 of the inorganic material layers falls within a range from 57% to 83% of distance A3 the centers of adjacent pixel separators 102 with photoelectric converters 101 interposed therebetween. On the other hand, in a cross-sectional view (e.g., a cross-section along the XZ-plane shown in FIG. 1) along the alignment of photoelectric converters 101 and inorganic material layers 301 (i.e., the Z-axis in this embodiment), width A1 of the inorganic material layers may fall within a range from 63% to 77% of distance A3 between the centers of adjacent pixel separators 102 with photoelectric converters 101 interposed therebetween.

In this embodiment, photoelectric converters 101 are rectangular in a plan view. In a plan view, each pixel separator 102 is in the form of a loop surrounding corresponding one of photoelectric converters 101 and having a uniform width and a rectangular periphery.

For example, in a cross-sectional view, distance A4 between sets of interconnect layers 201, more specifically, distance A4 that is the shortest distance between interconnect layer 201 right above one of two pixel separators 102 shown in FIG. 1 and interconnect layer 201 right above the other is longer than width A1 of inorganic material layers 301. For example, width A2 between inorganic material layers 302 is larger than distance A4 between sets of interconnect layers 201.

Width A2 of inorganic material layers 302 (e.g., the maximum length along the X-axis shown in FIG. 1) is 6.0 μm, for example.

Inorganic material layers 302 are conformal to corresponding inorganic material layers 301 and has a height (i.e., thickness along the Z-axis) substantially identical to a width (i.e., thickness along the X-axis) from inorganic material layer 301.

In this embodiment, as shown in FIG. 2 which will be described later, inorganic material layers 301 are in a square shape with the same length along the X- and y-axes.

The heights of condenser 300 and inorganic material layers 301 and 302 may be any values.

FIG. 2 is a plan view showing condenser 300 according to an embodiment.

As shown in FIG. 2, inorganic material layers 301 and 302 have an area increasing with a decrease in a distance to the top in a plan view. Specifically, inorganic material layers 302, which are formed on the upper surface of inorganic material layers 301 so as to cover inorganic material layer 301, have an area larger than that of inorganic material layer 301 in a plan view.

In this embodiment, inorganic material layers 301 and 302 are in a rectangular (more specifically, square) shape in a plan view. The centers of inorganic material layers 301 and 302 overlap each other. Although not shown, in photodetectors 10, the centers of inorganic material layers 301, inorganic material layers 302, photoelectric converters 101 overlap each other in a plan view.

As described above, condenser 300 may be light-transmissive. For example, if photodetectors 10 is used to detect near-infrared external light, condenser 300 is transmissive to the near-infrared external light.

For example, condenser 300 is made of an inorganic material.

Here, inorganic material layers 301, which are the lower layers of condenser 300, are films with a higher refractive index than that of inorganic material layers 302 which are the upper layers covering inorganic material layers 301. Specifically, inorganic material layers 301 have a higher refractive index to near-infrared external light than that of inorganic material layers 302.

Inorganic material layers 301 are SiN layers made of SiN, for example.

Inorganic material layers 302 are, for example, SiO₂ layers made of tetraethyl orthosilicate (TEOS).

Inorganic material layers 302 are rounded at the corners (i.e., stepped surfaces 340 in FIG. 1) of inorganic material layers 301. That is, the outer edges of the upper surfaces of inorganic material layers 302 are curved. More specifically, the outer edges of the upper surfaces (i.e., stepped surfaces 340) of inorganic material layers 302 are curved to project to the outside of condenser 300 and have round corners.

With rounded stepped surfaces 340, condenser 300 is locally (i.e., at the corners) in the same shape as the on-chip lens (e.g., a typical lens with a curved upper surface).

Accordingly, if these rounded corners are regarded as a part of a circle, the external light incident on inorganic material layers 302 tends to be refracted at the center of the circle. The rounded corners with a properly set curvature easily orients the external light incident on condenser 300 (more specifically, inorganic material layers 302) to photoelectric converters 101. As a result, the light collection efficiency of photodetectors 10 improves.

Condenser 300 with the double layer structure of inorganic material layers 301 and 302 has been described above. The structure is however not limited to the double-layer, and inorganic material layers 301 and 302 may be a multi-layer.

### [Manufacturing Method]

Next, a method of manufacturing photodetectors 10 will be described with reference to FIGS. 3A to 3D. FIGS. 3A to 3D are cross-sectional views for describing the method of manufacturing photodetectors 10.

First, photoelectric converters 101 and pixel separators 102 are formed in semiconductor substrate 100. Pixel separators 102 are formed around photoelectric converters 101 in a plan view of semiconductor substrate 100. Specifically, as shown in FIG. 3A, photoelectric converters 101 and pixel separators 102 are formed in semiconductor substrate 100, and multilayer 200 is formed on semiconductor substrate 100 (specifically, on main surface 110). For example, ion implantation is employed for forming photoelectric converters 101 and pixel separators 102. By ion implantation from main surface 110 of semiconductor substrate 100 made of silicon, photoelectric converters 101 and pixel separators 102 are formed on a relatively upper part inside semiconductor substrate 100 so as to be exposed from main surface 110, for example.

Multilayer 200 is formed as follows.

First, a Cu multi-layer interconnect structure is formed on main surface 110 of semiconductor substrate 100 including photoelectric converters 101 and pixel separators 102 by dual damascene (DD) process. In the DD process, after forming the original interconnect layer, liner layers 203 and interlayer insulating films 202 are deposited by chemical vapor deposition (CVD).

Then, interconnect grooves (in other words, trenches) and vias (more specifically, through-holes for forming vias 204) are patterned by lithography. After that, trenches and vias (i.e., through-holes) are formed in interlayer insulating films 202 by dry etching.

Subsequently, a barrier layer that reduces the diffusion of Cu and a Cu seed layer for flowing a current at the time of electroplating are disposed on the inner walls of the trenches and vias (i.e., through-holes) by physical vapor deposition (PVD). After that, a Cu film is embedded in the trenches and via (i.e., through-holes) by Cu electroplating.

In addition, the excessive Cu film and barrier layer on the interconnect layers are removed by chemical mechanical polishing (CMP), thereby forming eventual interconnect layers 201 including interconnect layers 201 and vias 204. After repeating this process, a Cu multi-layer interconnect structure is obtained which includes a predetermined number of interconnect layers 201. That is, multilayer 200 is formed by DD.

Next, as shown in FIG. 3B, inorganic material layer 303 for forming condenser 300 are deposited on multilayer 200 by CVD. Condenser 300 is formed as follows.

A resist film (not shown) is deposited for forming holes (i.e., separation grooves 330 shown in FIG. 3C) by lithography, and dry etching is performed using the deposited resist film as a mask.

Accordingly, as shown in FIG. 3C, inorganic material layers 301 in a size of each photodetector 10 and separation grooves 330 for separating inorganic material layers 301 for each pixel (i.e., photodetector 10) are formed. As etching gas, for example, carbon fluoride (CF) gas is used. After that, the resist film is removed by ashing.

Next, as shown in FIG. 3D, inorganic material layers 302 are deposited by CVD using an inorganic material, which has a refractive index lower than that of inorganic material layers 301, to cover inorganic material layers 301.

Through the process shown in FIGS. 3B to 3D, condenser 300 is formed as follows which is opposed to photoelectric converters 101 and includes inorganic material layers 301, and inorganic material layers 302 with a refractive index lower than that of inorganic material layers 301. Inorganic material layers 301 are formed to overlap photoelectric converters 101 at least partially in a plan view so that the outer edges of inorganic material layers 301 are located more inward than interconnect layers 201, which overlap pixel separators 102, in a plan view. Inorganic material layers 302 are formed to cover inorganic material layers 301. Specifically, in addition, multilayer 200 including interconnect layers 201 that overlap pixel separators 102 in a plan view is formed above semiconductor substrate 100, and condenser 300 is formed above multilayer 200.

By the method of manufacturing photodetectors 10 described above, inorganic material layers 301 and 302 are formed. Inorganic material layers 301 are formed on the uppermost surface (i.e., the upper surface) of multilayer 200 including interconnect layers 201. Inorganic material layers 301 are divided (i.e., separated) by separation grooves 330 above pixel separators 102 and interconnect layers 201. Inorganic material layers 302, which cover inorganic material layers 301 and include grooves 350 above pixel separators 102 and interconnect layers 201, can be formed on inorganic material layers 301.

### [Experimental Results]

Now, the experimental results (i.e., simulation results) of the light collection efficiency of photodetectors 10 according to the present disclosure will be described.

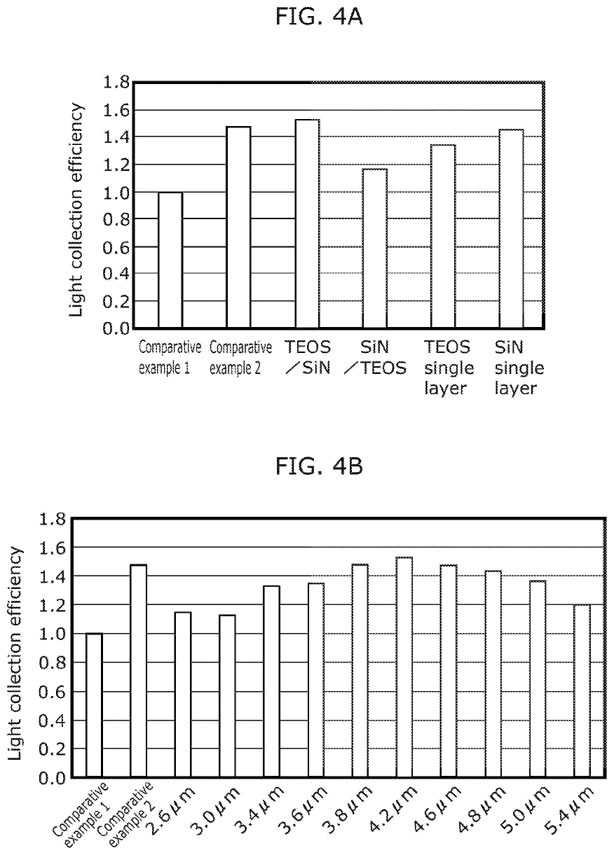

FIG. 4A is a graph showing the light collection efficiency of photodetectors 10 according to the present disclosure. In the graph shown in FIG. 4A, the vertical axis represents the following percentage (i.e., light collection efficiency) normalized with the light collection efficiency of a photodetector according to Comparative Example 1 (i.e., an experimental result at the left end of FIG. 4A). The percentage is a ratio of the amount of light that has reached photoelectric converters 101 to the amount of light (i.e., external light) incident in a direction orthogonal to main surface 110 toward condenser 300. The photodetector according to Comparative Example 1 includes no element above multilayer 200, that is, includes multilayer 200 in contact with air. A photodetector according to Comparative Example 2 includes a condenser that is a lens made of an organic material, which has been typically used, and having an upper surface in a circular shape as a whole. In other respects, the photodetector according to Comparative Example 2 has the same configuration as the photodetectors according to the present disclosure.

FIG. 4A also shows the light collection efficiencies of four types of the inorganic materials used for inorganic material layers 301 and 302 included in photodetectors 10. The experimental results shown in FIG. 4A are, in the order from left: a result of Comparative Example 1; a result of Comparative Example 2; a result of using inorganic material layers 301 made of SiN and inorganic material layers 302 made of TEOS (TEOS/SiN); a result of using inorganic material layers 301 made of TEOS and inorganic material layers 302 made of SiN (SiN/TEOS); a result of using inorganic material layers 301 and 302 made of TEOS (i.e., a TEOS single layer); and a result of using inorganic material layers 301 and 302 made of SiN (i.e., a SiN single layer).

In the simulations shown in FIG. 4A, SiN has a refractive index of 1.9, while TEOS has a refractive index of 1.46.

In the simulations shown in FIG. 4A, external light incident on the condenser has a wavelength of 940 nm.

Assume that condenser 300 includes inorganic material layers 301 made of SiN and inorganic material layers 302 made of TEOS (“TEOS/SiN” shown in FIG. 4A). In this case, as shown in FIG. 4A, such a condenser exhibits a light collection efficiency higher than that of Comparative Example 1, and higher than or substantially equal to that of the condenser according to Comparative Example 2 made of an organic material.

On the other hand, assume that the condenser is a single layer (e.g., a “TEOS single layer” and a “SiN single layer” shown in FIG. 4A) or that condenser 300 includes inorganic material layers 301 made of TEOS and inorganic material layers 302 made of SiN (“SiN/TEOS”) shown in FIG. 4A). In these cases, such condensers exhibit light collection efficiencies higher than that of Comparative Example 1 but lower than the light collection efficiency of Comparative Example 2.

In this manner, condenser 300 including inorganic material layers 301, and inorganic material layers 302 with a refractive index lower than that of inorganic material layers 301 can be manufactured simply and exhibits a light collection efficiency higher than or substantially equal to those of the comparative examples.

FIG. 4B is a graph showing a relationship between width A1 of inorganic material layers 301 included in photodetector 10 according to the present disclosure and the light collection efficiency.

In the graph shown in FIG. 4B, the vertical axis represents the following percentage (i.e., light collection efficiency) normalized with the light collection efficiency of the photodetector according to Comparative Example 1 (i.e., the experimental result at the left end of FIG. 4B). The percentage is the ratio of the amount of light that has reached photoelectric converters 101 to the amount of light (i.e., external light) incident in a direction orthogonal to main surface 110 toward condenser 300. The photodetector according to Comparative Example 1 includes no element above multilayer 200, that is, includes multilayer 200 in contact with air. The photodetector according to Comparative Example 2 includes the condenser that is the lens made of the organic material, which has been typically used, and having the upper surface in a circular shape as a whole. In other respects, the photodetector according to Comparative Example 2 has the same configuration as the photodetectors according to the present disclosure.

FIG. 4B shows the light collection efficiencies of inorganic material layers 301 included in photodetectors 10 with seven different widths A1.

The experimental results shown in FIG. 4B are, in the order from left: a result of Comparative Example 1; a result of Comparative Example 2; a result of using inorganic material layers 301 with width A1 of 2.6 μm, a result of using inorganic material layers 301 with width A1 of 3.0 μm, a result of using inorganic material layers 301 with width A1 of 3.4 μm, a result of using inorganic material layers 301 with width A1 of 3.6 μm, a result of using inorganic material layers 301 with width A1 of 3.8 μm, a result of using inorganic material layers 301 with width A1 of 4.2 μm, a result of using inorganic material layers 301 with width A1 of 4.6 μm, a result of using inorganic material layers 301 with width A1 of 4.8 μm, a result of using inorganic material layers 301 with width A1 of 5.0 μm, and a result of using inorganic material layers 301 with width A1 of 5.4 μm.

In the simulations shown in FIG. 4B, inorganic material layers 301 are made of SiN, while inorganic material layers 302 are made of TEOS. In the simulations shown in FIG. 4B, SiN has a refractive index of 1.9, while TEOS has a refractive index of 1.46. In the simulations shown in FIG. 4B, external light incident on the condenser has a wavelength of 940 nm.

In the simulations shown in FIG. 4B, distance A3 shown in FIG. 1 is 6.0 μm. Width A1 of 2.6 μm is about 0.43 times (i.e., 43%) distance A3. Width A1 of 3.0 μm is about 0.5 times (i.e., 50%) distance A3. Width A1 of 3.4 μm is about 0.57 times (i.e., 57%) distance A3. Width A1 of 3.6 μm is about 0.6 times (i.e., 60%) distance A3. Width A1 of 3.8 μm is about 0.63 times (i.e., 63%) distance A3. Width A1 of 4.2 μm is about 0.7 times (i.e., 70%) distance A3. Width A1 of 4.6 μm is about 0.77 times (i.e., 77%) of distance A. Width A1 of 4.8 μm is about 0.8 times (i.e., 80%) distance A3. Width A1 of 5.0 μm is about 0.83 times (i.e., 83%) distance A3. Width A1 of 5.4 μm is about 0.9 times (i.e., 90%) distance A3.

With width A1 higher than or equal to 4.8 μm, inorganic material layers 301 overlap interconnect layers 201 partially in a plan view.

As shown in FIG. 4B, a condenser including inorganic material layers 301 and 302 exhibits a light collection efficiency higher than that of Comparative Example 1. A condenser with width A1 within a range from 3.4 μm to 5.0 μm secures a light collection efficiency of 0.9 times (i.e., 90%) the light collection efficiency of Comparative Example 2. A condenser with width A1 within a range from 3.8 μm to 4.6 μm exhibits a light collection efficiency higher than or substantially equal to that of Comparative Example 2. This may be because, in a condenser with width A1 of 4.8 μm or more, inorganic material layers 301 overlap interconnect layers 201 partially in a plan view and light is thus reflected or absorbed by interconnect layers 201. In a condenser with width A1 of 3.6 μm or lower, inorganic material layers 301 has an area smaller than the width (i.e., the cell size) of photodetectors 10 in a plan view, which is believed to cause deterioration of the light collection efficiency.

As described above, inorganic material layers 301 are arranged so that the outer edges of inorganic material layers 301 are located more inward than interconnect layers 201, which are arranged right above pixel separators 102, in a plan view. This arrangement causes less deterioration of the light collection efficiency.

For example, a condenser with width A1 within a range from 0.57 times (i.e., 57%) to 0.83 times (i.e., 83%) distance A3 achieves a light collection efficiency of 90% or more the light collection efficiency of Comparative Example 2. For example, a condenser with width A1 within a range from 0.63 times (i.e., 63%) to 0.77 times (i.e., 77%) distance A3 achieves a light collection efficiency higher than or substantially equal to that of Comparative Example 2.

### [Advantages]

As described above, photodetectors 10 include semiconductor substrate 100; photoelectric converters 101 in semiconductor substrate 100; condenser 300 light-transmissive and opposed to photoelectric converters 101. Condenser 300 includes inorganic material layers 301 that overlap photoelectric converters 101 at least partially in a plan view, inorganic material layers 302, which cover inorganic material layers 301 and has a refractive index lower than that of inorganic material layers 301.

With this configuration, inorganic material layers 301 and 302 improve the light collection efficiency. Simply by forming inorganic material layers 302 to cover inorganic material layers 301, the light collection efficiency improves. Accordingly, condenser 300 can be formed more simply than a typical lens (i.e., condenser) made of an organic material with an upper surface in a circular shape as a whole. In addition, photodetectors 10 exhibit an improved light collection efficiency at photoelectric converters 101.

A typical lens made of an organic material has poor temperature characteristics due to the organic material. Upon application of a temperature of 200° C., for example, lens characteristics deteriorate, which limits the manufacturing process after the formation of the lens. By contrast, condenser 300 is made of an inorganic material and thus has excellent temperature characteristics. This allows application of a high-temperature manufacturing process even after the formation of the lens. Accordingly, options in the manufacturing process increase and the reliability of the lens characteristics improves.

For example, in a plan view, the outer edges of inorganic material layers 301 are located more inward than interconnect layers 201 that overlap pixel separators 102 arranged around photoelectric converters 101 in semiconductor substrate 100.

As described with reference to FIG. 4B, inorganic material layers 301 are arranged so that the outer edges of inorganic material layers 301 are located more inward than interconnect layers 201 arranged right above pixel separators 102 in a plan view. This arrangement causes less deterioration in the light collection efficiency.

For example, in a cross-sectional view along the alignment of photoelectric converters 101 and inorganic material layers 301, inorganic material layers 301 has a width within a range from 57% to 83% of the distance between the centers of adjacent pixel separators 102 with photoelectric converters 101 interposed therebetween.

With such a configuration, as described with reference to FIG. 4B, photodetectors 10 achieve a light collection efficiency of 90% or more the light collection efficiency of a typical lens made of an organic material.

For example, in a cross-sectional view along the alignment of photoelectric converters 101 and inorganic material layers 301, inorganic material layers 301 has a width within a range from 63% to 77% the distance between the centers of adjacent pixel separators 102 with photoelectric converters 101 interposed therebetween.

With such a configuration, as described with reference to FIG. 4B, photodetectors 10 achieve a light collection efficiency higher than or substantially equal to that of a typical lens made of an organic material.

For example, photodetectors 10 include multilayer 200 including interconnect layers 201. In this embodiment, semiconductor substrate 100, multilayer 200, and condenser 300 are stacked in this order.

That is, photodetectors 10 according to this embodiment may serve as FSI photodetectors.

For example, the refractive index of inorganic material layers 302 falls within a range from 1.3 to 1.6.

Inorganic material layers 302 are located in contact with air. Air has a refractive index of about 1. The refractive index of inorganic material layers 302 is set to be closer to the refractive index of air, for example, within a range from 1.3 to 1.6, thereby reducing the reflection of light at the interface between inorganic material layers 302 and the air. Such a configuration thus improves the light collection efficiency of photodetectors 10.

For example, inorganic material layers 302 are films containing Si and at least any of O or C, specifically, SiOx or SiOC, for example.

Accordingly, the refractive index of inorganic material layers 302 may fall within a range from 1.3 to 1.6, for example. Such a configuration thus improves the light collection efficiency of photodetectors 10.

For example, inorganic material layers 301 has a refractive index within a range from 1.6 to 2.5.

Accordingly, inorganic material layers 302 tend to emit incident external light toward photoelectric converters 101 due to the difference in the refractive index from inorganic material layers 301. In addition, inorganic material layers 301 with a refractive index of 2.2 or lower reduces the reflection of external light at the interface between inorganic material layers 301 and 302. Such a configuration thus improves the light collection efficiency of photodetectors 10.

For example, inorganic material layers 301 are films containing Si and at least any of O, N, or C, or films containing Ti and O, specifically, SiN, SiON, SiCN, SiCO, or TiOₓ, for example.

Accordingly, for example, the refractive index of inorganic material layers 301 falls within a range from 1.6 to 2.5. Such a configuration thus improves the light collection efficiency of photodetectors 10.

For example, condenser 300 is transmissive to near-infrared external light. More specifically, inorganic material layers 301 and 302 are transmissive to near-infrared external light.

Specifically, photodetectors 10 are, for example, assumed to image an object by detecting near-infrared external light. In this case, the light detected by photodetectors 10 has a wavelength (wavelength range) within a range from 750 nm to 1400 nm, which is the wavelength range of near-infrared external light longer than that of visible light. That is, even designed (manufactured) in a large size, condenser 300 with a structure for collecting near-infrared external light can collect near-infrared external light more efficiently than a condenser with a structure for collecting visible light. Accordingly, photodetectors 10 can be manufactured more simply. Since such photodetectors can be achieved by a simply manufacturing process, condenser 300 can be manufactured simply in a smaller pixel size to improve the light collection efficiency.

For example, the outer edges of the upper surfaces of inorganic material layers 302 are curved.

Accordingly, less light is reflected at the outer edges than in the case where the upper surfaces of inorganic material layers 302 have sharp outer edges. With the outer edges with a properly set curvature, light (i.e., external light) incident on inorganic material layers 302 can be refracted properly toward photoelectric converters 101. With such a configuration, the light collection efficiency of the photodetectors further improves.

For example, inorganic material layers 302 include grooves 350 recessed toward semiconductor substrate 100 above interconnect layers 201 that overlap pixel separators 102 around photoelectric converters 101 in semiconductor substrate 100 in a plan view.

In such a configuration, for example, the outer edges of inorganic material layers 302 are curved like stepped surfaces 340 due to grooves 350, which easily orients the external light toward photoelectric converters 101.

For example, in an arrangement of a plurality of photodetectors 10, interconnect layers 201 are located below gaps between adjacent inorganic material layers 301.

In such a configuration, the entry of the external light into photoelectric converters 101 is less hindered by interconnect layers 201.

For example, photodetectors 10 further include multilayer 200 including interconnect layers 201 and liner layer 205 above interconnect layers 201. In this case, for example, liner layer 205 has a refractive index lower than that of inorganic material layers 301 and higher than that of inorganic material layers 302.

In such a configuration, less light is reflected at the interfaces between inorganic material layers 301 and liner layer 205. Accordingly, further more light is collected by condenser 300 and incident on photoelectric converters 101.

A method of manufacturing photodetectors 10 according to an embodiment includes: forming photoelectric converters 101 in semiconductor substrate 100; and forming condenser 300 that is opposed to photoelectric converters 101 and includes inorganic material layers 301, and inorganic material layers 302 with a refractive index lower than that of inorganic material layers 301 by: forming inorganic material layers 301 to overlap photoelectric converters 101 at least partially in a plan view; and forming inorganic material layers 302 to cover inorganic material layers 301.

Accordingly, photodetectors 10 with a light collection efficiency improved by inorganic material layers 301 and 302 can be manufactured simply.

For example, the method of manufacturing photodetectors 10 according to the embodiment further includes forming, above semiconductor substrate 100, multilayer 200 including interconnect layers 201 to overlap pixel separators 102 in a plan view; and forming condenser 300 above multilayer 200.

Accordingly, FSI photodetectors 10 with a light collection efficiency improved by inorganic material layers 301 and 302 can be manufactured simply.

### [Variations of Photodetector]

Now, variations of the photodetectors will be described. In the following variations, differences from photodetectors 10 will be described mainly. Detailed description of the same configurations as photodetectors 10 may be omitted or simplified.

### [Variation 1]

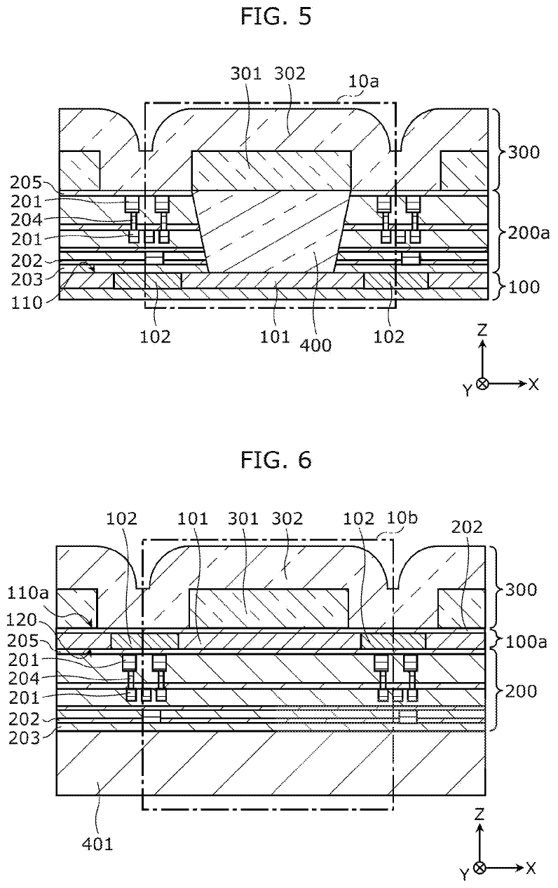

FIG. 5 is a cross-sectional view showing photodetectors 10a according to Variation 1 of the embodiment.

As shown in FIG. 5, photodetector 10a include waveguides 400 in addition to the configuration of photodetectors 10.

In photodetectors 10, condenser 300 is formed on the uppermost surface of multilayer 200 including metal interconnects.

Condenser 300 may be formed on the uppermost surfaces of waveguides 400 in multilayer 200a.

Multilayer 200a is a multilayer film that corresponds to multilayer 200 included in photodetectors 10 and further includes grooves for arranging waveguides 400.

Photodetectors 10a shown in FIG. 5 include waveguides 400 penetrating multilayer 200a between photoelectric converters 101 and condenser 300 so as to introduce light into photoelectric converters 101.

Waveguides 400 are light-transmissive optical waveguides for introducing incident light into photoelectric converters 101. A material employed for waveguides 400 is, for example, silicon nitride, silicon oxynitride, silicon carbonitride, carbon-added silicon oxide, or silicon oxide.

Waveguides 400 are interposed between photoelectric converters 101 and condenser 300. Specifically, waveguides 400 penetrate multilayer 200a between photoelectric converters 101 and condenser 300. In other words, multilayer 200a includes waveguides 400 between photoelectric converters 101 and condenser 300.

In this variation, waveguides 400 penetrate multilayer 200a and are in contact with photoelectric converters 101. Alternatively, interlayer insulating films 202 may be interposed between waveguides 400 and photoelectric converters 101.

The three-dimensional shape of waveguides 400 is, for example, a truncated quadrangular pyramid. The radius (or width) of waveguides 400 in a cross-sectional view increases with an increasing distance from photoelectric converters 101 in the stacking direction. For example, the radius of waveguides 400 is about 3.6 μm at the bottom, which is the closest to photoelectric converters 101, and 4.0 μm at the top, which is the farthest from photoelectric converters 101.

Waveguides 400 are formed as follows. For example, multilayer 200 is formed and then patterned by lithography and dry etching to form multilayer 200a. After that, an inorganic material, such as silicon nitride, silicon oxynitride, silicon carbonitride, or carbon-added silicon oxide, with a higher refractive index, or a silicon oxide film is deposited by CVD.

A material employed for waveguides 400 may have the same refractive index as condenser 300 (more specifically, inorganic material layers 301). Specifically, waveguides 400 and inorganic material layers 301 may be made of the same material.

Condenser 300 and waveguides 400 may be in contact with each other. That is, condenser 300 and waveguides 400 may be continuous. In other words, condenser 300 and waveguides 400 may be integral with each other.

In this configuration, waveguides 400 and inorganic material layers 301 have the same refractive index and are directly in contact with each other with no other member interposed therebetween. Less light is reflected between condenser 300 and waveguides 400. Accordingly, the light collection efficiency of photodetectors 10a improves.

In this manner, in addition to the configuration of photodetectors 10 (i.e., the FSI structure including semiconductor substrate 100, multilayer 200a, and condenser 300 stacked in this order), photodetectors 10a further include waveguides 400. Waveguides 400 penetrate multilayer 200a between photoelectric converters 101 and condenser 300 and are for introducing light into photoelectric converters 101.

Accordingly, waveguides 400 efficiently guide the external light collected by condenser 300 to photoelectric converters 101. As a result, the light collection efficiency of photodetectors 10a further improves.

### [Variation 2]

FIG. 6 is a cross-sectional view showing photodetectors 10b according to Variation 2 of the embodiment.

Photodetectors 10 shown in FIG. 1 are what are called “FSI photodetectors” including multilayer 200, which includes interconnect layers 201 and other layers, on main surface 110 of semiconductor substrate 100. The photodetectors according to the present disclosure are not limited thereto.

For example, photodetectors 10b may be what are called “back side illumination (BSI) photodetectors including multilayer 200, which includes interconnect layers 201 (more specifically, interlayer insulating films 202 between sets of interconnect layers 201) on back surface 120 which is opposite to main surface 110a of semiconductor substrate 100. That is, photodetectors 10b according to this variation include multilayer 200, semiconductor substrate 100a, and condenser 300 stacked in this order.

In this embodiment, interconnect layers 201 are located right below pixel separators 102.

Photodetectors 10b according to Variation 2 of the embodiment include, for example, semiconductor substrate 100a, multilayer 200, condenser 300, and support substrate 401.

Semiconductor substrate 100a includes photoelectric converters 101 and pixel separators 102.

Formed on main surface 110a of semiconductor substrate 100a are interlayer insulating films 202. That is, in photodetectors 10b, condenser 300 is formed on main surface 110a, which is the upper surfaces of interlayer insulating films 202 included in semiconductor substrate 100a. Accordingly, semiconductor substrate 100a and condenser 300 are electrically insulated from each other.

Support substrate 401 is for supporting multilayer 200. A material employed for support substrate 401 is not particularly limited. Support substrate 401 may be a ceramic substrate or a semiconductor substrate.

### [Variation 3]

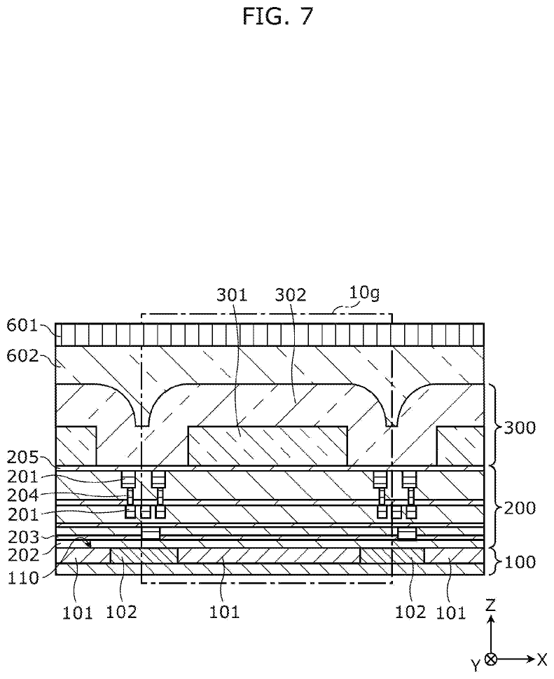

FIG. 7 is a cross-sectional view showing photodetectors 10g according to Variation 3 of the embodiment.

Photodetectors 10g include wavelength selector 601 above condenser 300. Specifically, wavelength selector 601 is located above the upper surface of condenser 300.

Wavelength selector 601 is an optical member for selectively allowing the entry of light with a predetermined wavelength to photoelectric converters 101. Specifically, wavelength selector 601 blocks light with at least some wavelengths out of external light by absorption or reflection, and causes light with the predetermined wavelength to pass. Wavelength selector 601 is a color filter, for example. A material of the color filter is, for example, an organic resin that blocks light with at least some wavelengths (e.g., light in a visible range) out of external light and causes light with a predetermined wavelength to pass.

Wavelength selector 601 may be a photonic filter. The photonic filter has a periodic multilayer structure obtained by alternately stacking a material with a low refractive index and a material with a high refractive index in a period corresponding to a wavelength. The photonic filter blocks light within a specific wavelength range determined by a structure parameter.

Provided right below wavelength selector 601 is planarization layer 602 to fill the gaps of grooves 350 in condenser 300.

Planarization layer 602 has a flat upper surface to place wavelength selector 601 properly. A material employed for planarization layer 602 only needs to be light-transmissive and may be any suitable material, such as a resin material or a glass material.

In this variation, the pixels (e.g., plurality of photodetectors 10g of a solid-state image sensor including the plurality of photodetectors 10g) may have the same selectivity or different selectivities of wavelength.

### [Variation 4]

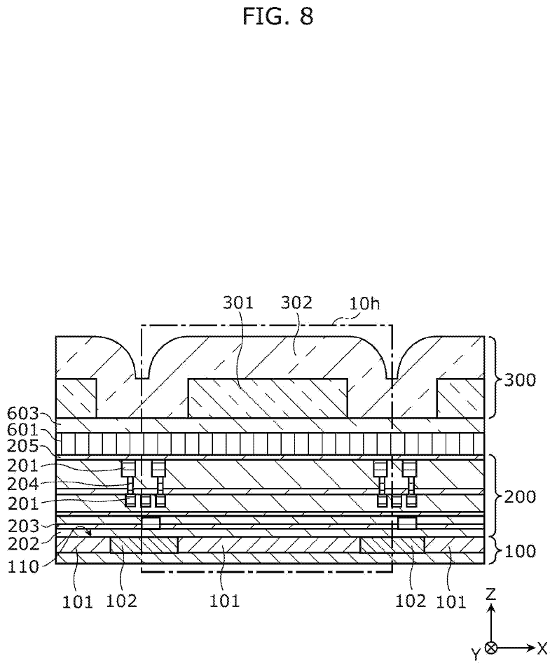

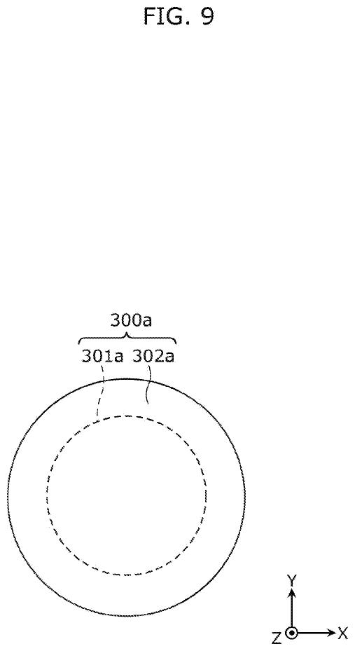

FIG. 8 is a cross-sectional view showing photodetectors 10h according to Variation 4 of the embodiment.

Photodetectors 10h include wavelength selector 601 between condenser 300 and interconnect layers 201. Specifically, wavelength selector 601 is located below condenser 300 and above interconnect layers 201.

In order to reduce processing damages of wavelength selector 601 at the time of forming inorganic material layers 301, protective film 603 is located right on wavelength selector 601.

Protective film 603 is for reducing processing damages of wavelength selector 601 at the time of forming inorganic material layers 301. A material employed for protective film 603 only needs to be light-transmissive and may be any suitable material, such as a resin material or a glass material.

In this variation as well as in Variation 3, the pixels (e.g., plurality of photodetectors 10h of a solid-state image sensor including the plurality of photodetectors 10h) may have the same selectivity or different selectivities of wavelength.

Condenser 300 is located on the uppermost layer of the multilayer structure of photodetectors 10h. After collecting external light, the wavelength of the collected external light can be selected by wavelength selector 601, which reduces color mixtures between the pixels.

### [Variations of Condenser]

Now, variations of the condenser included in photodetectors will be described. In the following variations, differences from condenser 300 included in photodetectors 10 will be described mainly. Detailed description of the same configurations as condenser 300 may be omitted or simplified.

### [Variation 1]

FIG. 9 is a plan view showing condenser 300a according to Variation 1.

Condenser 300a is in a circular shape in a plan view. More specifically, inorganic material layers 301a and inorganic material layers 302a included in condenser 300a are in a circular shape in a plan view and the centers thereof are substantially in the identical position.

### [Variation 2]

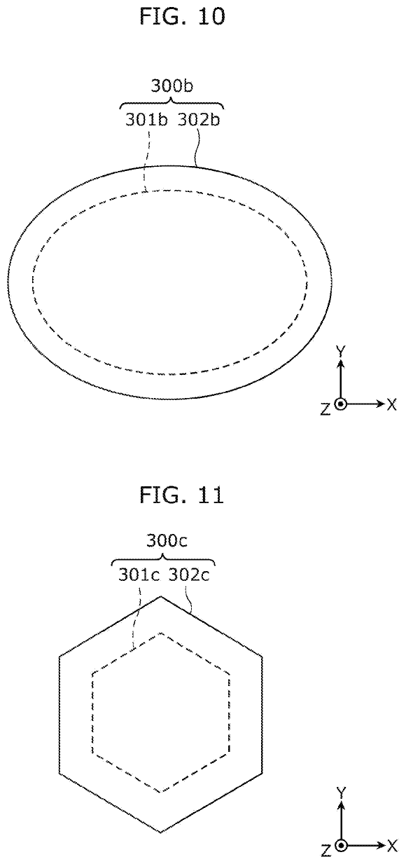

FIG. 10 is a plan view showing condenser 300b according to Variation 2.

Condenser 300b is in an oval shape in a plan view. More specifically, inorganic material layers 301b and inorganic material layers 302b included in condenser 300b are in an oval shape in a plan view and the centers thereof are substantially in the identical position.

### [Variation 3]

FIG. 11 is a plan view showing condenser 300c according to Variation 3.

Condenser 300c is in a hexagonal (more specifically, regular hexagonal) shape in a plan view. More specifically, inorganic material layers 301c and inorganic material layers 302c included in condenser 300c are in a hexagonal shape in a plan view and the centers thereof are substantially in the identical position.

As described above in Variations 1 to 3, condenser 300 shown in FIG. 2 is, for example, in a quadrilateral (specifically, rectangular, and more specifically, square) shape in a plan view. The shape of the condenser included in the photodetectors according to the present disclosure in a plan view is not limited thereto.

Note that the shape of photoelectric converters 101 in a plan view is not particularly limited but may be substantially identical to the shape of condenser in a plan view. Accordingly, the external light collected by the condenser can be incident on photoelectric converters 101 more efficiently.

### [Configuration of Solid-State Image Sensor]

The present disclosure may be implemented as a line sensor obtained by arranging a plurality of photoelectric converters 101 in a line in semiconductor substrate 100. Alternatively, the present disclosure may be implemented as a solid-state image sensor obtained by arranging a plurality of photoelectric converters 101 in a matrix in semiconductor substrate 100.

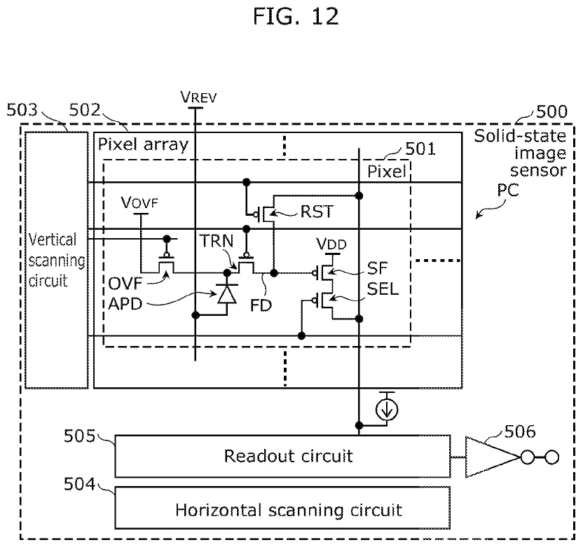

FIG. 12 shows solid-state image sensor 500 according to an embodiment.

As shown in FIG. 12, solid-state image sensor 500 includes pixel array 502 of a plurality of pixels 501, vertical scanning circuit 503, horizontal scanning circuit 504, readout circuit 505, and buffer amplifier (amplifier circuit) 506. Pixel array 502 is obtained by arranging photoelectric converters 101 in a matrix along the XY plane in photodetectors 10, 10a, or 10b. In the example of FIG. 12, photoelectric converters 101 are avalanche photodiodes which will also be referred to as “APDs”. Readout circuit 505 reads out signals output by pixel array 502.

Each pixel 501 includes pixel circuit PC including APD, transfer transistor TRN, reset transistor RST, floating diffusion region FD, amplification transistor SF, selection transistor SEL, and overflow transistor OVF.

In this embodiment, MOS transistors (MOSFETs) will be simply referred to as “transistors”. However, transistors constituting the pixel circuit of solid-state image sensor 500 are not limited to MOS transistors but may be junction transistors (JFETs), bipolar transistors, or a combination of these transistors.

The signal charges detected by the APD are transferred via transfer transistor TRN to floating diffusion region FD. Signals corresponding to the amount of the signal charges detected by sequentially selected pixel 501 by vertical scanning circuit 503 and horizontal scanning circuit 504 are transmitted via amplification transistor SF to readout circuit 505.

The signals obtained by pixels 501 are output from readout circuit 505 via buffer amplifier 506 to a signal processing circuit (not shown). After being subjected to signal processing, such as white balance, by the signal processing circuit (not shown), the signals are transferred to a display (not shown) or a memory (not shown) to create an image.

Overflow transistor OVF is a protective element, at which a current starts flowing once a potential of APD reaches a certain value. That is, overflow transistor OVF limits a voltage to be applied to APD. Once the APD detects light at a high multiplication, a current starts flowing at overflow transistor OVF before the voltage of the APD exceeds the breakdown voltage of transfer transistor TRN. Also, once the APD detects intense light so that the voltage at the time of reset becomes negative, a current starts flowing at overflow transistor OVF before the voltage of the APD exceeds the breakdown voltage of transfer transistor TRN. That is, solid-state image sensor 500 with overflow transistor OVF can be designed so that the voltage of the APD does not reach the breakdown voltage. The upper limit of the voltage applied to the APD is controllable by the threshold voltage of overflow transistor OVF, a voltage applied to the gate of overflow transistor OVF, or drain voltage (V_{OVF}) of overflow transistor OVF.

In pixel circuit PC shown in FIG. 12, peripheral circuits (i.e., vertical scanning circuit 503, horizontal scanning circuit 504, readout circuit 505, and buffer amplifier 506) are added to pixel array 502. Solid-state image sensor 500 does not necessarily include such peripheral circuits.

Pixel circuit PC includes five transistors (i.e., transfer transistor TRN, reset transistor RST, amplification transistor SF, selection transistor SEL, and overflow transistor OVF) and floating diffusion region FD. Pixel circuit PC is not limited to such a configuration. Solid-state image sensor 500 may include more or less transistors as long as being operatable.

The circuit configuration of pixel circuit PC is an example. Pixel circuit PC may have any other circuit configuration capable of reading signal charges stored in the APDs.

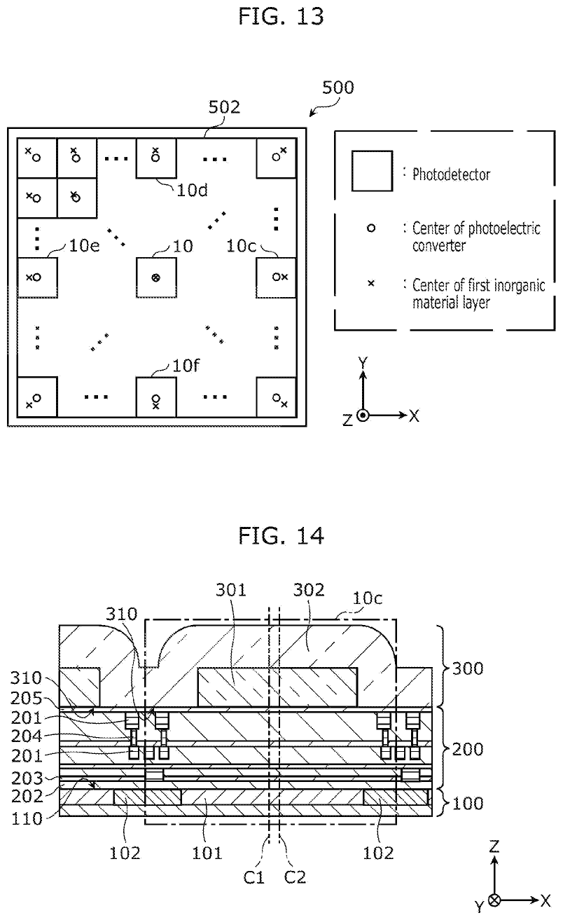

FIG. 13 shows a layout of a plurality of photodetectors included in solid-state image sensor 500 according to an embodiment. FIG. 14 is a cross-sectional view showing example photodetectors included in solid-state image sensor 500 according to the embodiment. In FIG. 13, the plurality of photodetectors included in pixel array 502 are represented by rectangles, the centers of respective photoelectric converters 101 of the photodetectors by circles, and the centers of respective first inorganic material layers (i.e., inorganic material layers 301) of the photodetectors by crosses.

As shown in FIG. 13, the plurality of photodetectors of solid-state image sensor 500 are arranged in a matrix in a plan view. In FIG. 13, some of the plurality of photodetectors are not shown.

Here, the arrangements of the respective components of the plurality of photodetectors of solid-state image sensor 500 are not necessarily identical. For example, in a plan view, the photodetector at the center of pixel array 502 and a photodetector at each end may have different positional relationships between the centers of photoelectric converter 101 and inorganic material layer 301.

As shown in FIG. 13, for example, solid-state image sensor 500 includes photodetector 10 at the center of pixel array 502 and photodetector 10c at an end (more specifically, the positive end of the X-axis in pixel array 502) in a plan view.

As shown in FIGS. 1 and 13, in photodetector 10, the centers of photoelectric converter 101 and inorganic material layers 301 overlap each other in a plan view. Specifically, in photodetector 10, the centers of photoelectric converter 101, inorganic material layer 301, and inorganic material layer 302 overlap each other in a plan view.

On the other hand, as shown in FIGS. 13 and 14, in photodetector 10c, the centers of photoelectric converter 101 and inorganic material layer 301 are shifted from each other in a plan view. Specifically, in photodetector 10c, center C2 of inorganic material layer 301 is shifted from center C1 of photoelectric converter 101 to the positive side of the X-axis. More specifically, in photodetectors 10c, center C2 of inorganic material layer 301 and the center of inorganic material layer 302 are shifted from center C1 of photoelectric converter 101 to the positive side of the X-axis. Center C2 of inorganic material layer 301 and the center of inorganic material layer 302 overlap each other in a plan view.

Similarly, in pixel array 502, in photodetector 10d at the positive end of the Y-axis, the center of inorganic material layer 301 is shifted from the center of photoelectric converter 101 to the positive side of the Y-axis. In pixel array 502, photodetector 10e at the negative end of the X-axis, the center of inorganic material layer 301 is shifted from the center of photoelectric converter 101 to the negative side of the X-axis. In pixel array 502, photodetector 10f at the negative end of the Y-axis, the center of inorganic material layer 301 is shifted from the center of photoelectric converter 101 to the negative side of the Y-axis.

In this manner, for example, in the photodetector at the center of pixel array 502, the centers of photoelectric converter 101 and inorganic material layer 301 overlap each other in a plan view. On the other hand, in the photodetector at each end of pixel array 502, the center of inorganic material layer 301 is shifted from the center of photoelectric converter 101 away from the center of the array. More specifically, in a photodetector at an end away from the center of pixel array 502 in a predetermined direction, the center of inorganic material layer 301 is shifted from the center of photoelectric converter 101 away from the center of the array in the predetermined direction.

Note that the centers described above may be, for example, the centers of gravity, or the centers of n-time rotations, where n is an integer of two or more.

For example, the center and ends described above may be set freely. For example, photodetectors on the outermost periphery of pixel array 502 in a plan view may be referred to as the “photodetectors at the ends”, and the others may be referred to as the “photodetectors at the center”. Alternatively, for example, assume that pixel array 502 includes N×M photodetectors, where N and M are each an integer of three or more. In this case, N/2×M/2 photodetectors closer to the center of pixel array 502 in a plan view may be referred to as the “photodetectors at the center”, and the others may be referred to as the “photodetectors at the ends”. For example, if N and M are each odd numbers, decimals may be rounded down.

The amount of the shift between the centers of photoelectric converter 101 and inorganic material layer 301 in a plan view may be set freely. For example, the amount of the shift between the centers of photoelectric converter 101 and inorganic material layer 301 may be determined in accordance with the distance from the center of the array in a plan view. For example, the amount of the shift between the centers of photoelectric converter 101 and inorganic material layer 301 may be set larger, with an increasing distance from the center of the array in a plan view.

Although not shown, in adjacent ones of the plurality of photodetectors of solid-state image sensor 500, interconnect layers 201 that connect the photodetectors and readout circuit 505 are located below the gaps between inorganic material layers 301.

As described above, solid-state image sensor 500 according to an embodiment includes pixel array 502 of the photodetectors described above (e.g., photodetectors 10, 10a, or 10b) arranged in a matrix, and readout circuit 505 that reads the signals output by pixel array 502.

Accordingly, like the photodetectors described above (e.g., photodetectors 10, 10a, or 10b), solid-state image sensor 500 can be manufactured more simply than before, and exhibit an improved light collection efficiency at photoelectric converters 101.

Note that solid-state image sensor 500 may include, as the photodetectors, photodetectors 10, 10a, or 10b. Alternatively, solid-state image sensor 500 may include any two or more types of photodetectors 10, 10a, and 10b.

In this embodiment, in a plan view, in pixel array 502, the photodetector (e.g., photodetector 10 in FIG. 13) at the center and the photodetectors (e.g., photodetectors 10c to 10f shown in FIG. 13) at the ends have different positional relationships between the centers of photoelectric converter 101 and inorganic material layer 301. More specifically, in this embodiment, in the photodetector at the center, the centers of photoelectric converter 101 and inorganic material layer 301 overlap each other in a plan view. On the other hand, in the photodetector at each end, the center of inorganic material layer 301 is shifted from the center of photoelectric converter 101 away from the center of the array.

For example, in pixel array 502, the photodetectors closer to the ends are more prone to the following problem. Once external light enters the light-receiving surface (e.g., main surface 110) obliquely (e.g., in a direction orthogonal to the Z-axis in this embodiment), the external light enters photoelectric converters 101 less properly. That is, at the ends of pixel array 502, the photodetectors have poor incident angle characteristics. To address the problem, the photodetectors at the ends of pixel array 502, the center of inorganic material layer 301 is shifted from the center of photoelectric converter 101 away from the center of the array. More specifically, in a photodetector at an end away from the center of pixel array 502 in a predetermined direction, the center of inorganic material layer 301 is shifted from the center of photoelectric converter 101 away from the center of the array in the predetermined direction. Accordingly, for example, even being incident obliquely from the normal of main surface 110 at an end of pixel array 502, the external light easily enters inorganic material layers 301. This causes less deterioration in the incident angle characteristics of the photodetector and improves the light collection efficiency of solid-state image sensor 500.

For example, interconnect layers 201 that connect photodetectors 10 and readout circuit 505 are located below the gaps between inorganic material layers 301 of adjacent photodetectors 10.

In such a configuration, the entry of the external light into photoelectric converters 101 is less hindered by interconnect layers 201.

### OTHER EMBODIMENTS

The photodetectors, for example, according to the embodiment and variations have been described above. The present disclosure is however not limited to the embodiment and variations described above.

For example, numerical values used in the embodiment described above for explanations are mere examples for specific description of the disclosure. The present disclosure is not limited to the numerical values used at the examples.

The embodiment and variations described above may be combined freely.

The example main materials of the layers of the multilayer structure of the photodetectors have been described above in the embodiment. The layers of the multilayer structure of the photodetectors may include other materials as long as achieving the same or similar functions as the multilayer structure described above in the embodiment. In the drawings, the corners and sides of the components are shown linearly. For manufacturing reasons, the present disclosure may include rounded corners and sides.

The present disclosure may include forms obtained by various modifications to the foregoing embodiment that can be conceived by those skilled in the art or forms achieved by freely combining the constituent elements and functions in the foregoing embodiment without departing from the scope and spirit of the present disclosure. For example, the present disclosure may be implemented as a method of manufacturing a photodetector.

### INDUSTRIAL APPLICABILITY

The photodetector according to the present disclosure is useful as a photodetector with a high light collection efficiency.

1. A photodetector comprising:
a semiconductor substrate;
a photoelectric converter in the semiconductor substrate; and
a condenser light-transmissive and opposed to the photoelectric converter, wherein
the condenser includes:
a first inorganic material layer at least partially overlapping the photoelectric converter in a plan view; and
a second inorganic material layer covering the first inorganic material layer and having a refractive index lower than a refractive index of the first inorganic material layer.

2. The photodetector according to claim 1, wherein
the second inorganic material layer includes:
a groove above an interconnect that overlaps, in a plan view, a pixel separator provided in the semiconductor substrate at a position around the photoelectric converter, the groove being recessed toward the semiconductor substrate.

3. The photodetector according to claim 2, further comprising:
a multilayer including the interconnect and a liner layer above the interconnect, wherein
the liner layer has a refractive index lower than the refractive index of the first inorganic material layer and higher than the refractive index of the second inorganic material layer.

4. The photodetector according to claim 1, wherein
the first inorganic material layer is a film containing Si and at least any of O, N, or C, or a film containing Ti and O.

5. The photodetector according to claim 1, wherein
the second inorganic material layer is a film containing Si and at least any of O or C.

6. The photodetector according to claim 3, wherein
the semiconductor substrate, the multilayer, and the condenser are stacked in this order.

7. The photodetector according to claim 6, further comprising:
a waveguide penetrating the multilayer between the photoelectric converter and the condenser so as to guide light to the photoelectric converter.

8. The photodetector according to claim 7, wherein
the waveguide and the first inorganic material layer are made of a same material.

9. The photodetector according to claim 8, wherein
the waveguide and the first inorganic material layer are in contact with each other.

10. The photodetector according to claim 3, wherein
the multilayer, the semiconductor substrate, and the condenser are stacked in this order.

11. The photodetector according to claim 1, wherein
the condenser is transmissive to near-infrared external light.

12. The photodetector according to claim 1, further comprising:
a wavelength selector located above the condenser to selectively allow entry of light with a predetermined wavelength to the photoelectric converter.

13. The photodetector according to claim 2, further comprising:
a wavelength selector located below the condenser and above the interconnect to allow entry of light with a predetermined wavelength to the photoelectric converter.

14. A solid-state image sensor comprising:
a pixel array obtained by arranging photodetectors, each being the photodetector according to claim 1, in a matrix; and
a readout circuit that reads a signal output from the pixel array.

15. The solid-state image sensor according to claim 14, wherein
a positional relationship between a center of the first inorganic material layer and a center of the photoelectric converter in a plan view is different between a photodetector at a center of the pixel array and a photodetector at an end.

16. The solid-state image sensor according to claim 15, wherein
in a plan view,
in the photodetector at the center of the pixel array, the center of the photoelectric converter overlaps the center of the first inorganic material layer, and
in the photodetector at the end, the center of the first inorganic material layer is shifted from the center of the photoelectric converter away from the center of the pixel array.

17. The solid-state image sensor according to claim 14, wherein
an interconnect that connects each of the photodetectors and the readout circuit is located below a gap between the first inorganic material layers of adjacent ones of the photodetectors.

18. A method of manufacturing a photodetector, the method comprising:
forming a photoelectric converter and a pixel separator around the photoelectric converter in a semiconductor substrate in a plan view of the semiconductor substrate; and
forming a condenser opposed to the photoelectric converter and including a first inorganic material layer and a second inorganic material layer with a refractive index lower than a refractive index of the first inorganic material layer by:
forming the first inorganic material layer to overlap the photoelectric converter at least partially in a plan view; and
forming the second inorganic material layer to cover the first inorganic material layer.

19. The method according to claim 18, further comprising:
forming, above the semiconductor substrate, a multilayer including an interconnect to overlap the pixel separator in a plan view; and
forming the condenser above the multilayer.
